(19) United States
(12) Patent Application Publication
(10) Pub. No.: US 2026/0329485 A1
(43) Pub. Date: Oct. 22, 2026

(54) STORAGE DEVICE

(71) Applicant: SONY SEMICONDUCTOR SOLUTIONS CORPORATION, KANAGAWA (JP)

(72) Inventor: KENTA SUZUKI, KANAGAWA (JP)

(21) Appl. No.: 19/103,550

(22) PCT Filed: Jun. 22, 2023
(86) PCT No.: PCT/JP2023/023217

§ 371 Date: Feb. 12, 2025

(30) Foreign Application Priority Data
Aug. 17, 2022 (JP) 2022-130195

(51) Int. Cl. G06F 3/06

(52) U.S. Cl. CPC G06F 3/0673; G06F 3/0604; G06F 3/0655

(57) ABSTRACT

Data held in a volatile storage unit can be stored into a variable resistance element, without intervention of any transistor of the volatile storage unit. A storage device includes: a volatile storage unit including a volatile storage node that complementarily holds data, and an access transistor connected between the volatile storage node and a bit line; and a nonvolatile storage unit including a nonvolatile storage node that complementarily holds the data, a first switch connected between the nonvolatile storage node and a store line, and a second switch connected between the nonvolatile storage node and the volatile storage node. The first switch includes a store transistor that stores data held in the volatile storage node into the nonvolatile storage node via the store line, and the second switch includes a restore transistor that restores data held in the nonvolatile storage node into the volatile storage node.

### TECHNICAL FIELD

The present technology relates to a storage device. More particularly, the present technology relates to a storage device in which a nonvolatile storage unit is provided in a volatile storage unit.

### BACKGROUND ART

There is a non-volatile (NV) static random access memory (SRAM) in which data is not lost even if a power abnormality or power-supply disconnection occurs. As such an NVSRAM, there is a proposed technology by which an N-channel transistor and a variable resistance element are interposed in series between a node and a bit line of the SRAM (see Patent Document 1, for example).

### CITATION LIST

### Patent Document

Patent Document 1: Japanese Patent Application Laid-Open No. 2013-125567

### SUMMARY OF THE INVENTION

### Problems to be Solved by the Invention

By the above conventional technology, however, an N-channel transistor and a variable resistance element are interposed in series with a bit line of an SRAM. For this reason, in a case where data is to be stored into a variable resistance element, a current flows through the variable resistance element via a transistor of the SRAM, which might cause an increase in the size of the transistors of the SRAM.

The present technology has been made in view of such circumstances, and aims to enable storing of data held in a volatile storage unit into a variable resistance element, without intervention of any transistor of the volatile storage unit.

### Solutions to Problems

The present technology has been made to solve the above problems, and a first aspect thereof is a storage device that includes: a volatile storage unit including a volatile storage node that complementarily holds data, and an access transistor connected between the volatile storage node and a bit line; and a nonvolatile storage unit including a nonvolatile storage node that complementarily holds the data, a first switch connected between the nonvolatile storage node and a store line, and a second switch connected between the nonvolatile storage node and the volatile storage node. This brings about an effect of separating the path through which the data held in the volatile storage node is stored into the nonvolatile storage node, from the path through which the data held in the nonvolatile storage node is restored into the volatile storage node.

Also, in the first aspect, the first switch may include a store transistor that stores data held in the volatile storage node into the nonvolatile storage node via the store line, and the second switch may include a restore transistor that restores data held in the nonvolatile storage node into the volatile storage node. This brings about an effect of storing the data held in the volatile storage node into the nonvolatile storage node via the first switch, and restoring the data held in the nonvolatile storage node into the volatile storage node via the second switch.

Also, in the first aspect, the volatile storage unit may be a static random access memory (SRAM), and the nonvolatile storage unit may be a resistive random access memory. This brings about an effect of adding a nonvolatile storage function to the SRAM.

Further, in the first aspect, the volatile storage unit may include a flip-flop having the volatile storage node, the nonvolatile storage unit may include a variable resistance element whose resistance changes on the basis of voltage application, and one end of the store transistor and one end of the restore transistor may be connected to one end of the variable resistance element. This brings about an effect that writing and reading of the volatile storage node are performed via the bit line, storing into the volatile storage node is performed via the store line, and restoring into the volatile storage node is performed without intervention of the bit line and the store line.

Also, in the first aspect, the flip-flop may include a pair of inverters whose outputs are connected to each other's input, a connecting point between the outputs and the inputs of the pair of inverters is used as the volatile storage node, and a connecting point among the variable resistance element, the store transistor, and the restore transistor is used as the nonvolatile storage node. This brings about an effect of storing the data held in the volatile storage node into the nonvolatile storage node, and restoring the data stored in the nonvolatile storage node into the volatile storage node.

Also, in the first aspect, the data held in the volatile storage node may be stored into the nonvolatile storage node sequentially via the store line and the store transistor. This brings about an effect of storing the data held in the volatile storage node into the nonvolatile storage node, without intervention of any bit line.

Further, in the first aspect, the data held in the nonvolatile storage node may be restored into the volatile storage node via the restore transistor. This brings about an effect of restoring the data held in the nonvolatile storage node into the volatile storage node, without intervention of any bit line and any store line.

Further, in the first aspect, the storage device may further include: a word line that opens and closes the access transistor; a restore select line that opens and closes the restore transistor; a store select line that opens and closes the store transistor; and a nonvolatile (NV) control line connected to the variable resistance element. This brings about an effect of separating the volatile storage node and the nonvolatile storage node at a time of storing, and connecting the volatile storage node and the nonvolatile storage node at a time of restoring.

Also, in the first aspect, the storage device may further include: a sense amplifier that detects data read from the volatile storage unit; and an NV control unit that controls a potential of the store line and a potential of the NV control line on the basis of the data detected by the sense amplifier, and stores the data held in the volatile storage node into the nonvolatile storage node via the store transistor. This brings about an effect of storing the data held in the volatile storage unit into the nonvolatile storage unit in a state where the volatile storage node and the nonvolatile storage node are separated.

Further, in the first aspect, when the data held in the volatile storage node is stored into the nonvolatile storage node, the NV control unit may complementarily set the potential of the store line depending on the data detected by the sense amplifier, and causes the potential of the control line to transition between a high level and a low level. This brings about an effect of storing data into the nonvolatile storage node in a complementary manner, on the basis of currents flowing in opposite directions in the variable resistance element.

Also, in the first aspect, the NV control unit may drive the nonvolatile storage unit on the basis of a higher voltage than a drive voltage of the volatile storage unit. This brings about an effect of coping with high-voltage driving of the nonvolatile storage unit while coping with low-voltage driving of the volatile storage unit.

Further, in the first aspect, the storage device may further include a power gating transistor that performs power gating of the inverter. This brings about an effect of restoring the data held in the nonvolatile storage node into the volatile storage node.

Also, in the first aspect, the drive force of the store transistor may be greater than the drive force of a transistor used in the inverter, a drive force of the access transistor, and a drive force of the restore transistor. This brings about an effect of adding a nonvolatile storage function to the volatile storage unit without an increase in the size of the volatile storage unit.

Further, in the first aspect, the storage device may include memory cells in which the volatile storage unit and the nonvolatile storage unit are provided, and the memory cells may be arranged in a row direction and a column direction in a matrix. This brings about an effect of adding a nonvolatile storage function for each memory cell having the volatile storage unit.

Also, in the first aspect, each of the word line, the restore select line, and the store select line may extend in the row direction, and each of the bit line, the store line, and the NV control line may extend in the column direction. This brings about an effect of selecting a memory cell for performing reading, writing, storing, and restoring, on the basis of an address specifying the memory cell.

Further, in the first aspect, the volatile storage unit may be a dual port SRAM. This brings about an effect of enabling two parallel read or write operations of the SRAM in one cycle, without changing the configuration of the dual port SRAM in a memory cell to which a nonvolatile storage function is added.

Also, in the first aspect, the volatile storage unit may be a two-port SRAM. This brings about an effect of enabling reading and writing of the SRAM in one cycle, without a change in the configuration of the two-port SRAM in a memory cell to which the nonvolatile storage function is added.

Also, in the first aspect, the storage device may further include a peripheral restore circuit that reads the data held in the nonvolatile storage node to the outside of the volatile storage unit. This brings about an effect of reading the data held in the nonvolatile storage unit, without intervention of the volatile storage unit.

Further, in the first aspect, the data held in the nonvolatile storage node may be restored into the peripheral restore circuit sequentially via the store transistor and the store line. This brings about an effect of restoring the data held in the nonvolatile storage unit into the peripheral restore circuit, without intervention of the volatile storage unit.

### BRIEF DESCRIPTION OF DRAWINGS

FIG. 1 is a diagram illustrating an example of configurations of a memory cell and a peripheral circuit of a storage device according to a first embodiment.

FIG. 2 is a block diagram illustrating an example configuration of a cell array of the storage device according to the first embodiment.

FIG. 3 is a chart showing an example of a voltage waveform of each component of a memory cell during a read operation according to the first embodiment.

FIG. 4 is a chart showing an example of a voltage waveform of each component of a memory cell during a write operation according to the first embodiment.

FIG. 5 is a chart showing an example of a voltage waveform of each component of a memory cell during a store operation according to the first embodiment.

FIG. 6 is a chart showing an example of a voltage waveform of each component of a memory cell during a restore operation according to the first embodiment.

FIG. 7 is a diagram illustrating an example configuration of a memory cell according to a comparative example.

FIG. 8 is tables showing size comparison between a memory cell according to the first embodiment and that according to the comparative example.

FIG. 9 is cross-sectional views illustrating example layouts of the wiring lines in a memory cell array according to the first embodiment.

FIG. 10 is a block diagram illustrating the overall configuration of the storage device according to the first embodiment.

FIG. 11 is a diagram illustrating an example configuration of a memory cell of a storage device according to a second embodiment.

FIG. 12 is a diagram illustrating an example configuration of a memory cell of a storage device according to a third embodiment.

FIG. 13 is a diagram illustrating an example configuration of a memory cell of a storage device according to a fourth embodiment.

FIG. 14 is a diagram illustrating an example configuration of a memory cell of a storage device according to a fifth embodiment.

FIG. 15 is a block diagram illustrating an example configuration of a cell array of the storage device according to the fifth embodiment.

FIG. 16 is a diagram illustrating an example configuration of a memory cell of a storage device according to a sixth embodiment.

FIG. 17 is a chart showing an example of a voltage waveform of each component of a memory cell during a peripheral restore operation according to the sixth embodiment.

FIG. 18 is a diagram illustrating an example of configurations of a memory cell and a peripheral circuit of a storage device according to a seventh embodiment.

### MODE FOR CARRYING OUT THE INVENTION

In the description below, modes for carrying out the present technology (these modes will be hereinafter referred to as embodiments) are will be explained. The explanation will be made in the following order.
1. First embodiment (an example in which store transistors that store data held in volatile storage nodes into nonvolatile storage nodes, and restore transistors that restore data stored in the nonvolatile storage nodes into the volatile storage nodes are provided in each memory cell)
2. Second embodiment (an example in which a dual port SRAM is provided in each memory cell)
3. Third embodiment (an example in which a two-port SRAM is provided in each memory cell)
4. Fourth embodiment (an example of a footer-type power gating configuration)
5. Fifth embodiment (an example in which a power gating transistor is shared among a plurality of memory cells)
6. Sixth embodiment (an example in which data held in a nonvolatile storage unit is read to the outside)
7. Seventh embodiment (an example in which a nonvolatile storage unit is driven with a higher voltage than the voltage for driving a volatile storage unit)

### 1. First Embodiment

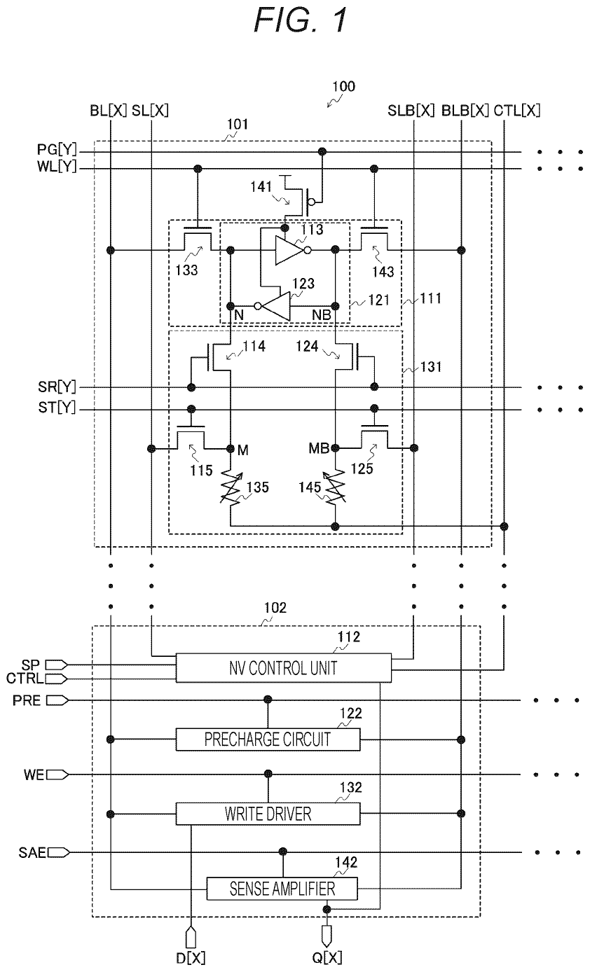

FIG. 1 is a diagram illustrating an example of configurations of a memory cell and a peripheral circuit of a storage device according to a first embodiment.

In the drawing, a storage device 100 includes memory cells 101 and column processing units 102. The memory cells 101 can be arranged in a row direction and a column direction in a matrix.

A memory cell 101 includes a volatile storage unit that holds data in a volatile manner, and a nonvolatile storage unit that holds data in a nonvolatile manner. At this point, the nonvolatile storage unit can hold, in a nonvolatile manner, the data that is held in the volatile storage unit. Also, the nonvolatile storage unit can write the data held in a nonvolatile manner by the nonvolatile storage unit, back into the volatile storage unit. Note that the term “volatile” as used herein means that electric power is required to hold data. Further, the term “nonvolatile” as used herein means that no electric power is required to hold data.

Note that, in the present specification, writing of data into the volatile storage unit is called “writing”, and reading of data from the volatile storage unit is called “reading”. Further, a process of causing the nonvolatile storage unit to hold the data held in the volatile storage unit is called “storing”, and a process of writing the data held in the nonvolatile storage unit back into the volatile storage unit is called “restoring”.

The memory cell 101 includes an SRAM 111 and a resistive random access memory 131. The SRAM 111 includes a flip-flop 121 and access transistors 133 and 143. The flip-flop 121 includes inverters 113 and 123.

The SRAM 111 includes volatile storage nodes N and NB that hold data in a complementary manner. Each of the volatile storage nodes N and NB holds data in a volatile manner. Note that the term “complementary” used herein refers to a relationship in which data ‘1’ is held in the volatile storage node NB when data ‘0’ is held in the volatile storage node N, and the data ‘0’ is held in the volatile storage node NB when the data ‘1’ is held in the volatile storage node N.

Each of the inverters 113 and 123 can be formed with a complementary metal oxide semiconductor (CMOS) transistor. For example, each of the inverters 113 and 123 may be formed with a PMOS transistor and an NMOS transistor that are connected in series.

An input of the inverter 113 is connected to an output of the inverter 123, and an input of the inverter 123 is connected to an output of the inverter 113. At this point of time, the volatile storage node N can be provided at the connecting point between the input of the inverter 113 and the output of the inverter 123, and the volatile storage node NB can be provided at the connecting point between the input of the inverter 123 and the output of the inverter 113.

The access transistor 133 is connected between the volatile storage node N and a bit line BL[X]. The access transistor 143 is connected between the volatile storage node NB and a bit line BLB[X]. Opening/closing of each of the access transistors 133 and 143 is controlled via a word line WL[Y]. Each of the access transistors 133 and 143 may be an NMOS transistor. At this point, the word line WL[Y] can be connected to the gate of each of the access transistors 133 and 143.

The power gating transistor 141 performs power gating of each of the inverters 113 and 123. At this point of time, the power gating transistor 141 can extract the charges accumulated in each of the volatile storage nodes N and NB into a power supply potential. Opening and closing of the power gating transistor 141 is controlled via a power gating line PG[Y]. The power gating transistor 141 may be a PMOS transistor. At this point, the power gating line PG[Y] can be connected to the gate of the power gating transistor 141.

The resistive random access memory 131 includes nonvolatile storage nodes M and MB that hold data in a complementary manner. Each of the nonvolatile storage nodes M and MB holds data in a nonvolatile manner. Note that the term “complementary” used herein refers to a relationship in which data ‘1’ is held in the nonvolatile storage node MB when data ‘0’ is held in the nonvolatile storage node M, and the data ‘0’ is held in the nonvolatile storage node MB when the data ‘1’ is held in the nonvolatile storage node M.

The resistive random access memory 131 includes variable resistance elements 135 and 145, store transistors 115 and 125, and restore transistors 114 and 124.

Each of the variable resistance elements 135 and 145 changes in resistance on the basis of voltage application, and maintains its resistance state even when the voltage application is cut off. At this point, a low-resistance state of each of the variable resistance elements 135 and 145 can be made to correspond to the data ‘0’, and a high-resistance state of each of the variable resistance elements 135 and 145 can be made to correspond to the data ‘1’. The variable resistance element 135 is connected between the nonvolatile storage node M and an NV control line CTL[X]. The variable resistance element 145 is connected between the nonvolatile storage node MB and the NV control line CTL[X].

The respective store transistors 115 and 125 store the data held in the respective volatile storage nodes N and NB into the respective nonvolatile storage nodes M and MB via store lines SL[X] and SLB[X], respectively. The store transistor 115 is connected between the nonvolatile storage node M and the store line SL[X]. The store transistor 125 is connected between the nonvolatile storage node MB and the store line SLB[X]. Opening and closing of each of the store transistors 115 and 125 is controlled via a store select line ST[Y]. Each of the store transistors 115 and 125 may be an NMOS transistor. At this point, the store select line ST[Y] can be connected to the gate of each of the store transistors 115 and 125.

The respective restore transistors 114 and 124 restore the data held in the respective nonvolatile storage nodes M and MB into the respective volatile storage nodes N and NB. The restore transistor 114 is connected between the volatile storage node N and the nonvolatile storage node M. The restore transistor 124 is connected between the volatile storage node NB and the nonvolatile storage node MB. Opening and closing of each of the restore transistors 114 and 124 is controlled via a restore select line SR[Y]. Each of the restore transistors 114 and 124 may be an NMOS transistor. At this point, the restore select line SR[Y] can be connected to the gate of each of the restore transistors 114 and 124.

The drive force of each of the store transistors 115 and 125 may be greater than the drive forces of the transistors of each of the inverters 113 and 123, each of the access transistors 133 and 143, and each of the restore transistors 114 and 124. At this point, the drive force of each of the store transistors 115 and 125 can be set on the basis of the electric current necessary for changing the state of each of the variable resistance elements 135 and 145.

The resistive random access memory 131 may be a magnetoresistive random access memory (MRAM), a phase change random access memory (PRAM), or a resistance random access memory (ReRAM).

The column processing units 102 can be provided for the respective columns. A column processing unit 102 includes a nonvolatile (NV) control unit 112, a precharge circuit 122, a write driver 132, and a sense amplifier 142.

The NV control unit 112 controls storing and restoring in the resistive random access memory 131, on the basis of a store control signal SP and an NV control signal CTRL. Here, the NV control unit 112 controls the potentials of the respective store lines SL[X] and SLB[X] and the potential of the NV control line CTL[X] on the basis of data detected by the sense amplifier 142, to conduct storing in the nonvolatile storage nodes M and MB. At this point of time, the NV control unit 112 can complementarily set the potentials of the respective store lines SL[X] and SLB[X] in accordance with the data detected by the sense amplifier 142, to cause the potential of the NV control line CTL[X] to transition between the high level and the low level.

The precharge circuit 122 precharges the respective bit lines BL[X] and BLB[X], on the basis of a precharge enable signal PRE.

The write driver 132 complementarily sets the potentials of the respective bit lines BL[X] and BLB[X], on the basis of a write enable signal WE. At this point, the write driver 132 can determine the potentials of the respective bit lines BL[X] and BLB[X], on the basis of write data D[X]. For example, when the write data D[X] is 0, the potential of the bit line BL[X] can be set to the low level, and the potential of BLB[X] can be set to the high level. When the write data D[X] is 1, the potential of the bit line BL[X] can be set to the high level, and the potential of BLB[X] can be set to the low level.

The sense amplifier 142 detects data read from the SRAM 111, on the basis of a sense enable signal SAE. At this point, at a time of reading of data from the SRAM 111, the potentials of the respective bit lines BL[X] and BLB[X] are complementarily set in accordance with the data stored in the SRAM 111. The sense amplifier 142 is then able to determine the data stored in the SRAM 111, on the basis of the potentials of the respective bit lines BL[X] and BLB[X]. The sense amplifier 142 outputs data Q[X] read from the SRAM 111 to the outside, and inputs the read data Q[X] to the NV control unit 112. At this point of time, the NV control unit 112 can control the potentials of the respective store lines SL[X] and SLB[X] in accordance with the data Q[X] read from the SRAM 111, and store the data held in the SRAM 111 into the resistive random access memory 131.

The bit lines BL[X] and BLB[X], the store lines SL[X] and SLB[X], and the NV control line CTL[X] extend in the column direction. X (X being an integer of 0 or greater) can indicate a column position. A column position can be designated on the basis of a column address. The word line WL[Y], the restore select line SR[Y], the store select line ST[Y], and the power gating line PG[Y] extend in the row direction. Y (Y being an integer of 0 or greater) can indicate a row position. A row position can be designated on the basis of a row address.

Note that the SRAM 111 is an example of the volatile storage unit disclosed in the claims. The resistive random access memory 131 is an example of the nonvolatile storage unit disclosed in the claims. Each of the store transistors 115 and 125 is an example of the first switch disclosed in the claims. Each of the restore transistors 114 and 124 is an example of the second switch disclosed in the claims.

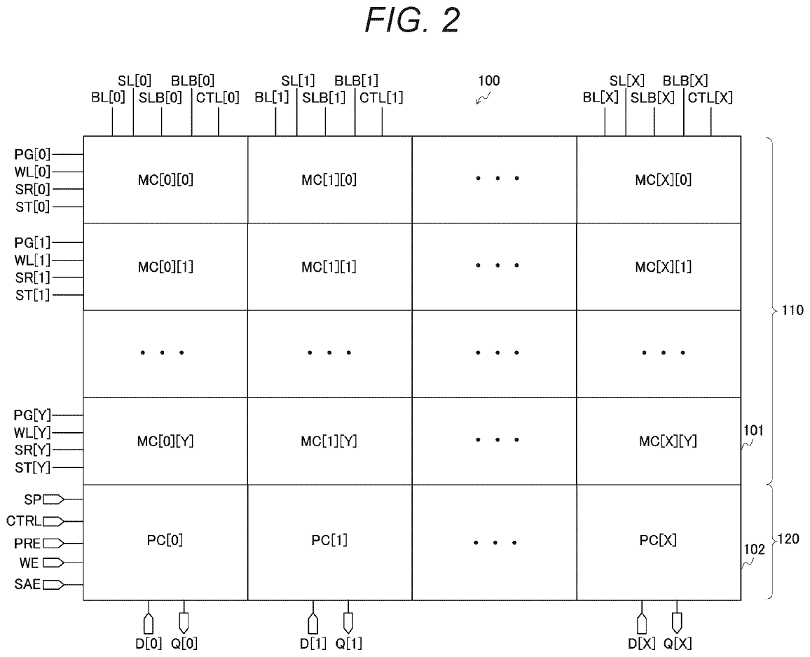

FIG. 2 is a block diagram illustrating an example configuration of a cell array of the storage device according to the first embodiment.

In the drawing, a memory cell array 110 and a peripheral circuit 120 are provided in the storage device 100. In the memory cell array 110, the memory cells 101 are arranged in the row direction and the column direction in a matrix. In the peripheral circuit 120, the column processing units 102 are provided for the respective columns. Note that, among the memory cells 101, MC[X] [Y] indicates that the column position is X, and the row position is Y. Among the column processing units 102, PC[X] indicates that the column position is X.

The bit lines BL[X] and BLB[X], the store lines SL[X] and SLB[X], and the NV control lines CTL[X] can be provided for the respective columns. The word lines WL[Y], the store select lines ST[Y], the restore select lines SR[Y], and the power gating lines PG[Y] can be provided for the respective rows. The write data D[X] can be input for each column, and the read data Q[X] can be output for each column.

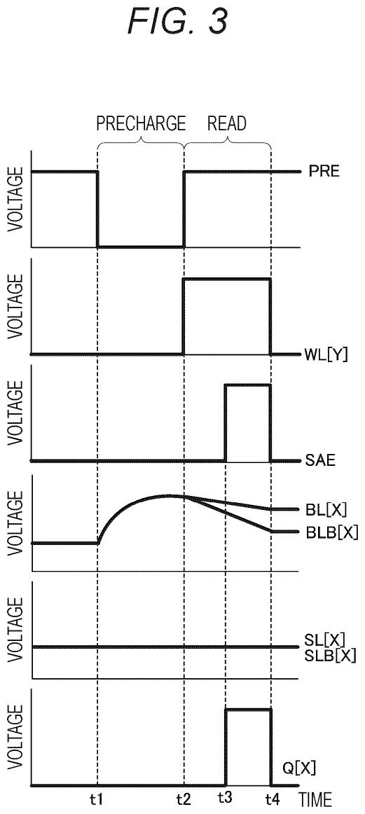

FIG. 3 is a chart showing an example of a voltage waveform of each component of a memory cell during a read operation according to the first embodiment.

In the drawing, during reading from the SRAM 111, the respective restore transistors 114 and 124 are turned off via the restore select lines SR[Y], and the SRAM 111 and the resistive random access memory 131 are disconnected from each other. Further, each of the store lines SL[X] and SLB[X] is put into a floating state (times t1 to t4).

When the precharge enable signal PRE transitions from the high level to the low level (time t1), the precharge circuit 122 then precharges each of the bit lines BL[X] and BLB[X].

Next, when the precharge enable signal PRE transitions from the low level to the high level (time t2), the precharge circuit 122 ends the precharging of each of the bit lines BL[X] and BLB[X]. Further, the respective access transistors 133 and 143 are turned on via the word lines WL[Y], and the respective volatile storage nodes N and NB are connected to the bit lines BL[X] and BLB[X]. At this point of time, the potentials of the respective bit lines BL[X] and BLB[X] change depending on the data held in the respective volatile storage nodes N and NB. For example, in a case where “1” is held in the volatile storage node N, and “0” is held in the volatile storage node NB, the potential of the bit line BLB[X] becomes lower than the potential of the bit line BL[X].

Next, when the sense enable signal SAE transitions from the low level to the high level (time t3), the sense amplifier 142 determines the data held in the SRAM 111, on the basis of the potentials of the respective bit lines BL[X] and BLB[X]. The sense amplifier 142 then outputs the read data Q[X] corresponding to the result of the determination.

When the reading from the SRAM 111 comes to an end, the respective access transistors 133 and 143 are turned off via the word lines WL[Y], and the sense enable signal SAE transitions from the high level to the low level (time t4).

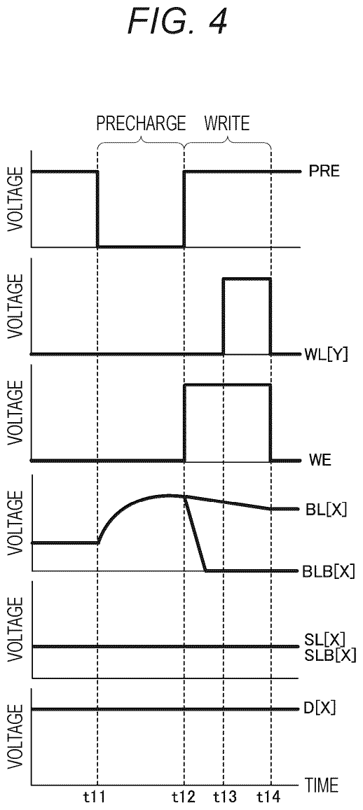

FIG. 4 is a chart showing an example of a voltage waveform of each component of a memory cell during a write operation according to the first embodiment.

In the drawing, at a time of writing into the SRAM 111, the respective restore transistors 114 and 124 are turned off via the restore select lines SR[Y], and the SRAM 111 and the resistive random access memory 131 are disconnected from each other. Further, each of the store lines SL[X] and SLB[X] is put into a floating state (times t11 to t13).

Then, when the precharge enable signal PRE transitions from the high level to the low level (time t11), the precharge circuit 122 then precharges each of the bit lines BL[X] and BLB[X].

Next, when the precharge enable signal PRE transitions from the low level to the high level (time t12), the precharge circuit 122 ends the precharging of each of the bit lines BL[X] and BLB[X]. Further, when the write enable signal WE transitions from the low level to the high level, the write driver 132 complementarily sets the potentials of the respective bit lines BL[X] and BLB[X], on the basis of the write data D[X]. For example, in a case where “1” is written into the volatile storage node N, and writing is performed on the volatile storage node NB, the write data D[X] is set to the high level (from time t11 to time t14). In a case where the write data D[X] is set to the high level, the write driver 132 then sets the bit line BL[X] to the high level, and sets BLB[X] to the low level.

Next, the respective access transistors 133 and 143 are turned on via the word lines WL[Y], and the respective volatile storage nodes N and NB are connected to the bit lines BL[X] and BLB[X] (time t13). When the respective volatile storage nodes N and NB are connected to the bit lines BL[X] and BLB[X], the potentials of the respective volatile storage nodes N and NB are set in accordance with the potentials of the respective bit lines BL[X] and BLB[X], and data corresponding to the potentials are held in the respective volatile storage nodes N and NB.

When the writing into the SRAM 111 comes to an end, the respective access transistors 133 and 143 are turned off via the word lines WL[Y], and the write enable signal WE transitions from the high level to the low level (time t14).

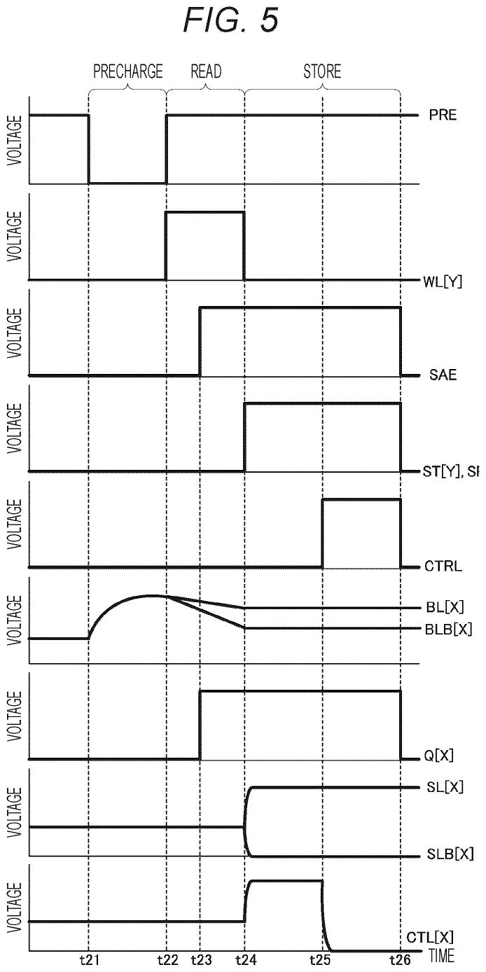

FIG. 5 is a chart showing an example of a voltage waveform of each component of a memory cell during a store operation according to the first embodiment.

In the drawing, at a time of storing into the resistive random access memory 131, the respective restore transistors 114 and 124 are turned off via the restore select lines SR[Y], and the SRAM 111 and the resistive random access memory 131 are disconnected from each other (from time t21 to time t25).

When the precharge enable signal PRE transitions from the high level to the low level (time t21), the precharge circuit 122 then precharges each of the bit lines BL[X] and BLB[X].

Next, when the precharge enable signal PRE transitions from the low level to the high level (time t22), the precharge circuit 122 ends the precharging of each of the bit lines BL[X] and BLB[X]. Further, the respective access transistors 133 and 143 are turned on via the word lines WL[Y], and the respective volatile storage nodes N and NB are connected to the bit lines BL[X] and BLB[X]. At this point of time, the potentials of the respective bit lines BL[X] and BLB[X] change depending on the data held in the respective volatile storage nodes N and NB. For example, in a case where “1” is held in the volatile storage node N, and “0” is held in the volatile storage node NB, the potential of the bit line BLB[X] becomes lower than the potential of the bit line BL[X].

Next, when the sense enable signal SAE transitions from the low level to the high level (time t23), the sense amplifier 142 determines the data held in the SRAM 111, on the basis of the potentials of the respective bit lines BL[X] and BLB[X]. The sense amplifier 142 then outputs the read data Q[X] corresponding to the result of the determination, to the NV control unit 112.

Next, the respective store transistors 115 and 125 are turned on via the store select lines ST[Y], and the respective nonvolatile storage nodes M and MB are connected to the store lines SL[X] and SLB[X] (time t24).

Further, when the store control signal SP transitions from the low level to the high level, the NV control unit 112 causes the potential of the NV control lines CTL[X] to transition from a floating state to the high level. Furthermore, the NV control unit 112 complementarily sets the potentials of the respective store lines SL[X] and SLB[X], in accordance with the read data Q[X] detected by the sense amplifier 142. For example, in a case where “1” is held in the volatile storage node N, and “0” is held in the volatile storage node NB, the NV control unit 112 sets the potential of the store line SL[X] to the high level, and sets the potential of SLB[X] to the low level. At this point of time, the potential of the NV control line CTL[X] is at the high level. Therefore, no current flows in the variable resistance element 145 that is connected between the NV control line CTL[X] and the store line SLB[X] via the store transistor 125. On the other hand, a current flows in the variable resistance element 135 that is connected between the NV control line CTL[X] and the store line SL[X] via the store transistor 115. Accordingly, the variable resistance element 135 is set to a high-resistance state, and the data ‘1’ is stored into the nonvolatile storage node M.

Next, when the NV control signal CTRL transitions from the low level to the high level, the NV control unit 112 causes the potential of the NV control line CTL[X] to transition from the high level to the low level (time t25). At this point of time, the potential of the store line SL[X] is at the high level, and the potential of SLB[X] is at the low level. Therefore, no current flows in the variable resistance element 135 that is connected between the NV control line CTL[X] and the store line SL[X] via the store transistor 115. On the other hand, a current flows in the variable resistance element 145 that is connected between the NV control line CTL[X] and the store line SLB[X] via the store transistor 125. At this point of time, the direction in which the current flows in the variable resistance element 145 in a case where the potential of the NV control signal CTRL is at the low level is the opposite to the direction in which the current flows in the variable resistance element 135 in a case where the potential of the NV control signal CTRL is at the high level. Accordingly, the variable resistance element 145 is set to a low-resistance state, and the data ‘0’ is stored into the nonvolatile storage node MB.

When the storing into the resistive random access memory 131 comes to an end, the respective store transistors 115 and 125 are turned off via the store select lines ST[Y] (time t26). Further, the sense enable signal SAE, the store control signal SP, and the NV control signal CTRL transition from the high level to the low level.

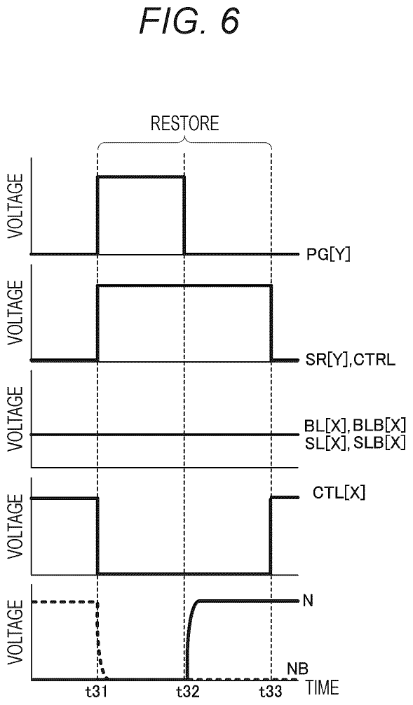

FIG. 6 is a chart showing an example of a voltage waveform of each component of a memory cell during a restore operation according to the first embodiment.

In the drawing, at a time of restoring into the SRAM 111, the respective store transistors 115 and 125 are turned off via the store select lines ST[Y], and the resistive random access memory 131 is disconnected from the store lines SL[X] and SLB[X]. Further, the respective bit lines BL[X] and BLB[X], and the respective store lines SL[X] and SLB[X] are put into a floating state (from time t31 to time t33).

The respective restore transistors 114 and 124 are then turned on via the restore select lines SR[Y], and the SRAM 111 and the resistive random access memory 131 are connected (time t31). Further, the power gating transistor 141 is turned off via the power gating line PG[Y]. Furthermore, when the NV control signal CTRL transitions from the low level to the high level, the NV control unit 112 causes the potential of the NV control lines CTL[X] to transition from the high level to the low level.

Here, it is assumed that the data ‘1’ is held in the nonvolatile storage node M, the data ‘0’ is held in the nonvolatile storage node MB, the variable resistance element 135 is in a high-resistance state, and the variable resistance element 145 is in a low-resistance state. At this point of time, a low-level voltage is applied to the volatile storage node NB from the NV control line CTL[X] via the variable resistance element 145, and the data ‘0’ is restored.

Next, the power gating transistor 141 is turned on via the power gating line PG[Y]. At this point of time, data is complementarily held in the respective volatile storage nodes N and NB, and the data ‘1’ is restored into the volatile storage node N (time t32).

When the restoring into the SRAM 111 comes to an end, the respective restore transistors 114 and 124 are turned off via the restore select lines SR[Y], and the NV control signal CTRL transitions from the high level to the low level (time t33).

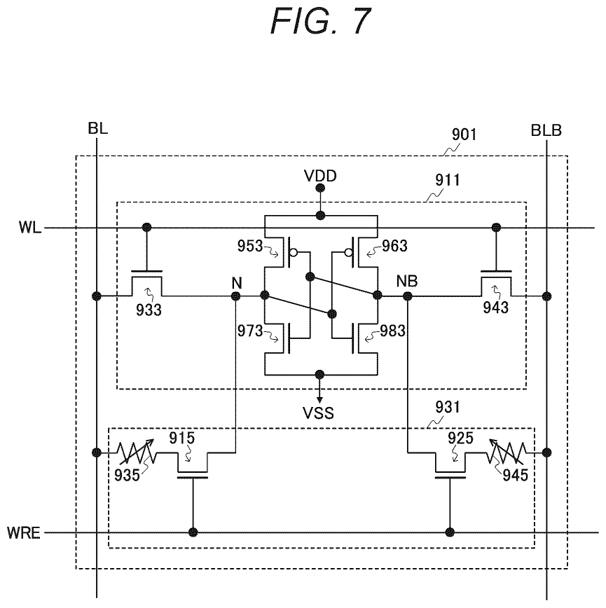

FIG. 7 is a diagram illustrating an example configuration of a memory cell according to a comparative example.

In the drawing, a memory cell 901 includes an SRAM 911 and a resistive random access memory 931. The SRAM 911 includes NMOS transistors 973 and 983, PMOS transistors 953 and 963, and access transistors 933 and 943. A high power supply voltage VDD and a low power supply voltage VSS are supplied to the SRAM 911. A word line WL is connected to the gates of the respective access transistors 933 and 943. A bit line BL is connected to a volatile node N of the SRAM 911 via the access transistor 933. A bit line BLB is connected to a volatile node NB of the SRAM 911 via the access transistor 943.

The resistive random access memory 931 includes variable resistance elements 935 and 945, and resistive drive transistors 915 and 925. The resistive drive transistor 915 is connected in series to the variable resistance element 935. The resistive drive transistor 925 is connected in series to the variable resistance element 945. Also, the resistive drive transistor 915 is connected to the volatile node N of the SRAM 911. The resistive drive transistor 925 is connected to the volatile node NB of the SRAM 911. Further, the variable resistance element 935 is connected to the bit line BL, and the variable resistance element 945 is connected to the bit line BLB. Each of the resistive drive transistors 915 and 925 performs both storing into the resistive random access memory 931 and restoring into the SRAM 911. A store/restore line WRE is connected to the gates of the respective resistive drive transistors 915 and 925.

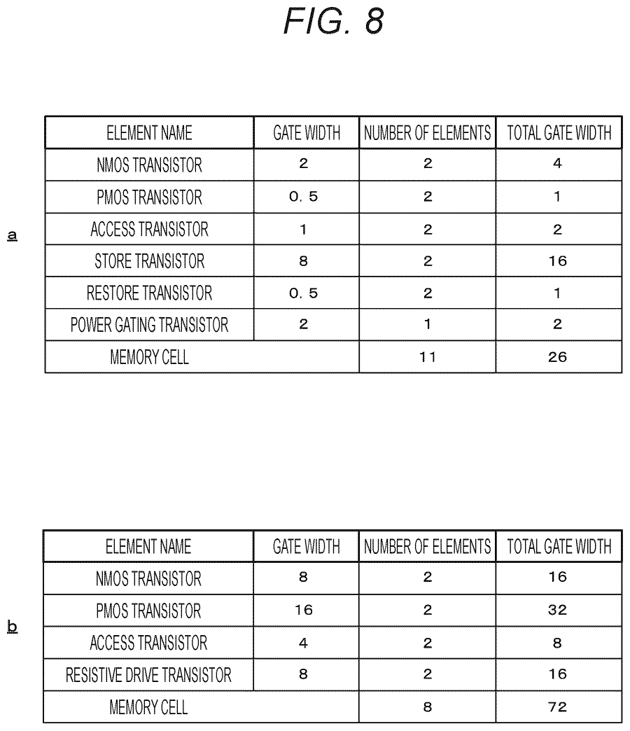

FIG. 8 is tables showing size comparison between a memory cell according to the first embodiment and that according to the comparative example. Note that a of FIG. 8 shows the sizes of transistor that are used in a memory cell 101 according to the first embodiment. b of FIG. 8 shows the sizes of transistors that are used in the memory cell 901 according to the comparative example illustrated in FIG. 7.

In a of FIG. 8, the SRAM 111 according to the first embodiment includes two NMOS transistors and two PMOS transistors that are used for the flip-flop 121, and two access transistors 133 and 143. Further, one power gating transistor 141 is added. In the resistive random access memory 131, two store transistors 115 and 125, and two restore transistors 114 and 124 are used. Here, the store transistors 115 and 125 are used to drive the variable resistance elements 135 and 145, and therefore, the gate width thereof is designed to be greater than those of the other transistors.

In b of FIG. 8, the SRAM 911 in FIG. 7 includes the two NMOS transistors 973 and 983, the two PMOS transistors 953 and 963, and the two access transistors 933 and 943. The resistive random access memory 931 includes the two resistive drive transistors 915 and 925. Here, the resistive drive transistors 915 and 925 are used to drive the variable resistance elements 935 and 945, and therefore, the gate width thereof is designed to be greater than those of the other transistors. At this point of time, the gate width of each of the resistive drive transistors 915 and 925 can be equal to the gate width of the store transistors 115 and 125. Furthermore, since the transistors of the SRAM 911 are included in the current path during driving of each of the variable resistance elements 935 and 945, each transistor of the SRAM 911 requires a drive force equivalent to that for each of the resistive drive transistors 915 and 925. Therefore, the gate width of each transistor of the SRAM is increased to match the gate width of each of the resistive drive transistors 915 and 925.

As a result, the number of elements in the memory cell 101 according to the first embodiment is larger than the number of elements in the memory cell 911 in FIG. 7, but the sum of the gate widths in the memory cell 101 according to the first embodiment is smaller than the sum of the gate widths in the memory cell 911 in FIG. 7. Accordingly, in the memory cell 101 according to the first embodiment, the cell size can be made smaller than that of the memory cell 911 in FIG. 7.

Furthermore, in the memory cell 901 in FIG. 7, the resistive drive transistor 915 is connected to the bit line BL via the variable resistance element 935, and the resistive drive transistor 925 is connected to the bit line BLB via the variable resistance element 945. Therefore, the junction capacitances of the respective resistive drive transistors 915 and 925 are added to the bit lines BL and BLB, and the off-leak currents of the respective resistive drive transistors 915 and 925 flow into the bit lines BL and BLB. At this point of time, the junction capacitance added to the bit line BL is expressed as (the capacitance of the access transistor 933+the capacitance of the resistive drive transistor 915)×the number of word lines. Also, the junction capacitance added to the bit line BLB is expressed as (the capacitance of the access transistor 943+the capacitance of resistive drive transistor 925)×the number of word lines. The off-leak current flowing in the bit line BL is expressed as (the off-leak current of the access transistor 933+the off-leak current of the resistive drive transistor 915)×the number of word lines. Also, the off-leak current flowing in the bit line BLB is expressed as (the off-leak current of the access transistor 943+the off-leak current of the resistive drive transistor 925)×the number of word lines.

In the memory cell 101 according to the first embodiment, on the other hand, the store transistors 115 and 125, and the restore transistors 114 and 124 are not connected to either of the bit lines BL and BLB. Accordingly, the junction capacitance of the respective store transistors 115 and 125, and the junction capacitance of the respective restore transistors 114 and 124 are not added to either of the bit lines BL and BLB. Likewise, the off-leak current of each of the store transistors 115 and 125, and the off-leakage current of each of the restore transistors 114 and 124 do not flow into either of the bit lines BL and BLB. At this point of time, the junction capacitance added to the bit line BL is expressed as the capacitance of the store transistor 115×the number of word lines. Likewise, the junction capacitance added to the bit line BLB is expressed as the capacitance of the store transistor 125×the number of word lines. The off-leak current flowing into the bit line BL is expressed as the off-leak current of the store transistor 115×the number of word lines. Likewise, the off-leak current flowing into the bit line BLB is expressed as the off-leak current of the store transistor 125×the number of word lines.

As a result, the memory cell 101 according to the first embodiment can lower power consumption, and improve the read and write performance of the SRAM 111, compared with the memory cell 901 in FIG. 7.

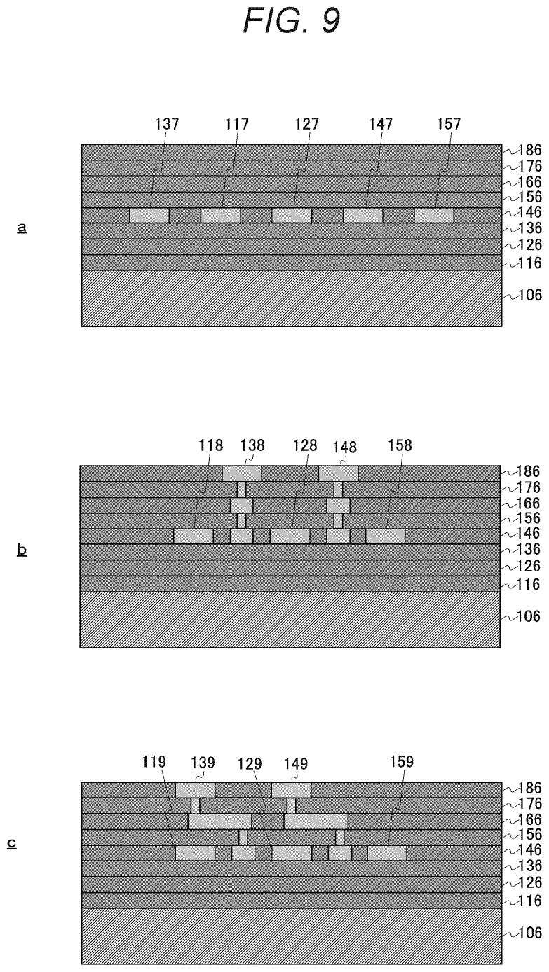

FIG. 9 is cross-sectional views illustrating example layouts of the wiring lines in a memory cell array according to the first embodiment. Note that a of FIG. 9 is a diagram illustrating a first example of the layout of the wiring lines of the memory cell array, b of FIG. 9 is a diagram illustrating a second example of the layout of the wiring lines in the memory cell array, and c of FIG. 9 is a diagram illustrating a third example of the layout of the wiring lines in the memory cell array. Further, FIG. 9 illustrates examples of four-layer wiring lines.

In a of the drawing, a gate electrode/via layer 116, a wiring layer 126, a via layer 136, a wiring layer 146, a via layer 156, a wiring layer 166, a via layer 176, and a wiring layer 186 are sequentially stacked on a semiconductor substrate 106. A device separation layer, an impurity diffusion layer, and a well layer may also be formed on the semiconductor substrate 106. The material of the semiconductor substrate 106 is Si, GaAs, SiC, or GaN, for example. Gate electrode and contact vias are formed in the gate electrode/via layer 116. Wiring lines are formed in each of the wiring layers 126, 146, 166, and 186. Vias are formed in each of the via layers 136, 156, and 176. The material of the wiring lines and the vias is Al or Cu, for example.

In the wiring layer 146, the bit lines BL[X] and BLB[X], the store lines SL[X] and SLB[X], and the NV control lines CTL[X] are formed. This wiring method is effective in the case of a layout in which the memory cells 101 are long in the row direction. In this case, the wiring layer 186 can be effectively used for other wiring lines. Note that signal lines can be provided in the row direction in the wiring layer 166.

In b of the drawing, the bit lines BL[X] and BLB[X], and the NV control lines CTL[X] are formed in the wiring layer 146. In the wiring layer 186, the store lines SL[X] and SLB[X] are formed. At this point of time, the wiring layer 146 of the bit lines BL[X] and BLB[X], and the wiring layer 186 of the store lines SL[X] and SLB[X] can be separated from each other. By this wiring method, the memory cells 101 in the row direction can be made smaller in size. This wiring method is effective in a case where the wiring area of the wiring layer 166 in the column direction has a margin.

In c of the drawing, the bit lines BL[X] and BLB[X], and the NV control lines CTL[X] are formed in the wiring layer 146. In the wiring layer 186, the store lines SL[X] and SLB[X] are formed. At this point of time, the store lines SL[X] and SLB[X] are disposed so as to overlap the bit lines BL[X] and BLB[X]. By this wiring method, the memory cells 101 in the row direction can be made smaller in size. This wiring method is effective in a case where the wiring area of the wiring layer 166 in the column direction has a margin.

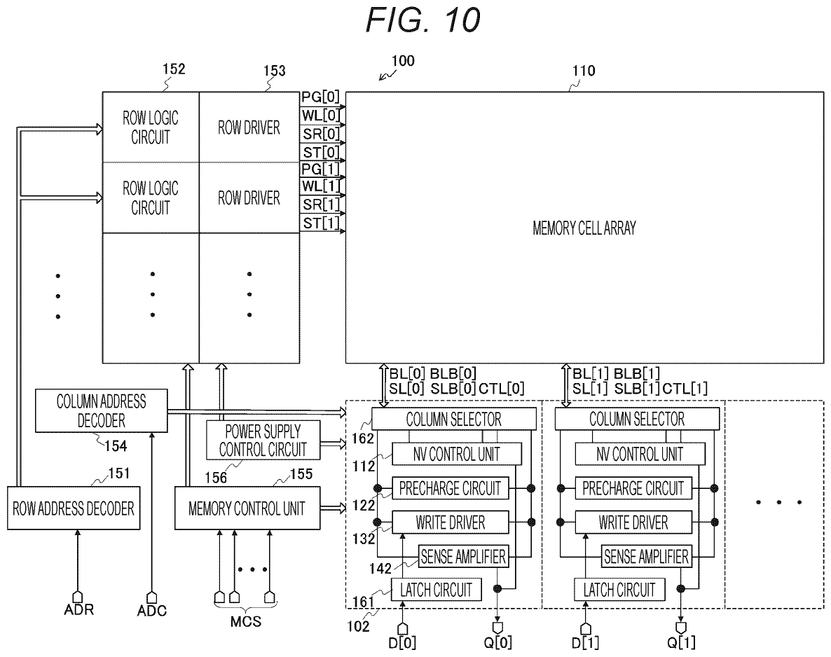

FIG. 10 is a block diagram illustrating the overall configuration of the storage device according to the first embodiment.

In the drawing, the storage device 100 includes a row address decoder 151, row logic circuits 152, row drivers 153, a column address decoder 154, a memory control unit 155, and a power supply control circuit 156, in addition to the memory cell array 110 and the column processing units 102. The column processing units 102 each include a latch circuit 161 and a column selector 162, in addition to the NV control unit 112, the precharge circuit 122, the write driver 132, and the sense amplifier 142. The row logic circuits 152 and the row drivers 153 are provided for the respective rows.

The row address decoder 151 selects a row on the basis of a row address ADR, and activates the row logic circuit 152 corresponding to the selected row. The row logic circuit 152 activates the row driver 153, on the basis of an instruction from the row address decoder 151. The row driver 153 drives the memory cell array 110 on a row basis. At this point of time, the row driver 153 can drive the power gating line PG[Y], the word line WL[Y], the restore select line SR[Y], and the store select line ST[Y] on a row basis.

The column address decoder 154 selects a column on the basis of a column address ADC, and activates the column processing unit 102 corresponding to the selected column. The latch circuit 161 latches the write data D[X], and outputs the write data D[X] to the write driver 132. The column selector 162 selects a column of the memory cell array 110. At this point of time, the column selector 162 can connect the store lines SL[X] and SLB[X] of the selected column and the NV control line CTL[X] to the NV control unit 112. Also, the column selector 162 can connect the bit lines BL[X] and BLB[X] of the selected column to the precharge circuit 122, the write driver 132, and the sense amplifier 142.

The memory control unit 155 controls the row logic circuits 152 and the column processing units 102, on the basis of a control signal MCS. The power supply control circuit 156 controls the power supplies to the row drivers 153 and the column processing units 102. At this point of time, the power supply control circuit 156 may control the power supplies to the row drivers 153 and the column processing units 102 so that the resistive random access memory 131 is driven on the basis of a voltage higher than the drive voltage for the SRAM 111.

In this manner, in the first embodiment described above, the store transistors 115 and 125 that store the data held in the SRAM 111 into the resistive random access memory 131 are provided in a memory cell 101. Further, the restore transistors 114 and 124 that restore the data stored in the resistive random access memory 131 into the SRAM 111 are provided in the memory cell 101. Thus, the data held in the SRAM 111 can be stored into the resistive random access memory 131 via the respective store transistors 115 and 125. Also, the data held in the resistive random access memory 131 can be restored into the SRAM 111 via the respective restore transistors 114 and 124. Accordingly, it is possible to separate the path through which the data held in the SRAM 111 is stored into the resistive random access memory 131, from the path through which the data held in the resistive random access memory 131 is restored into the SRAM 111. As a result, the data held in the SRAM 111 can be stored into the resistive random access memory 131 without intervention of the SRAM 111, and it is not necessary to drive the resistive random access memory 131 via the SRAM 111 at a time of storing of data. Thus, it is not necessary to increase the size of the SRAM 111 to store data into the resistive random access memory 131, and it is possible to add a nonvolatile storage function to the SRAM 111 while preventing an increase in the size of the memory cells 101.

Further, to make current flow in the variable resistance elements 135 and 145 at a time of storing of data, the store lines SL[X] and SLB[X] are provided separately from the bit lines BL[X] and BLB[X]. The store transistor 115 is then connected between the store line SL[X] and the variable resistance element 135, and the store transistor 125 is connected between the store line SLB[X] and the variable resistance element 145. Accordingly, it is possible to prevent the junction capacitances of the respective store transistors 115 and 125 from being added to the respective bit lines BL[X] and BLB[X], and it is possible to prevent an increase in parasitic capacitance of each of the bit lines BL[X] and BLB[X]. Thus, the discharge time of each of the bit lines BL[X] and BLB[X] can be prevented from increasing, and the write time and the read time of the SRAM 111 can be prevented from increasing. Also, the charge/discharge amount in each of the bit lines BL[X] and BLB[X] can be prevented from increasing, and the power consumption by the SRAM 111 can be prevented from increasing.

Further, it is possible to prevent an instantaneous current from flowing in the variable resistance elements 135 and 145 at a time of amplification of each of the bit lines BL[X] and BLB[X], and it is possible to prevent an increase in noise at a time of reading from and writing into the SRAM 111.

### 2. Second Embodiment

In the first embodiment described above, an SRAM 111 is provided as a volatile storage unit in a memory cell 101. In this second embodiment, a dual port SRAM is provided as a volatile storage unit in a memory cell.

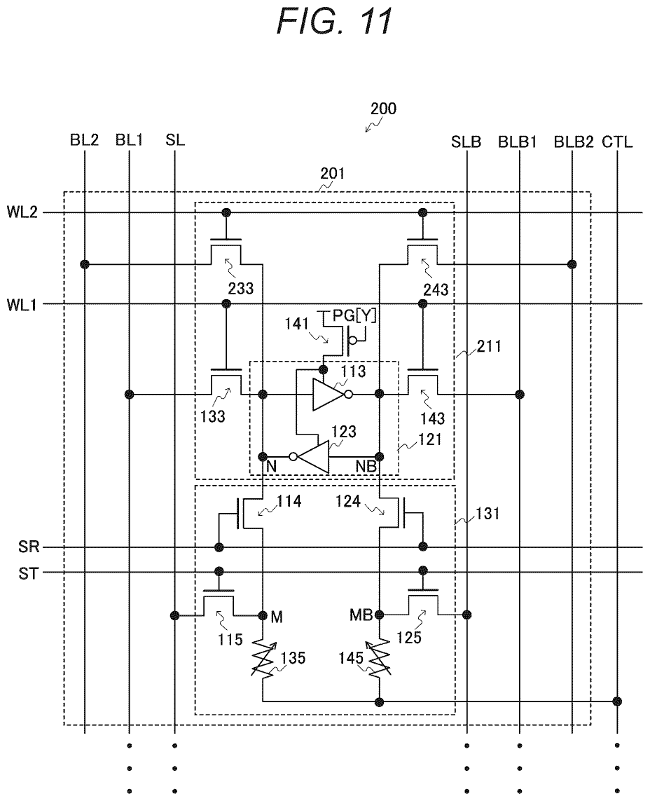

FIG. 11 is a diagram illustrating an example configuration of a memory cell of a storage device according to the second embodiment.

In the drawing, a storage device 200 includes memory cells 201, instead of the memory cells 101 of the first embodiment described above. The storage device 200 also includes word lines WL1 and WL2 as the word lines WL[Y] of the first embodiment described above. The storage device 200 further includes bit lines BL1, BLB1, BL2, and BLB2 as the bit lines BL[X] and BLB[X] of the first embodiment described above. The other components of the storage device 200 of the second embodiment are similar to the components of the storage device 100 of the first embodiment described above.

A memory cell 201 includes an SRAM 211, instead of the SRAM 111 of the first embodiment described above. The other components of the memory cell 201 are similar to the components of the memory cell 101 of the first embodiment described above.

In the SRAM 211, access transistors 233 and 243 are added to the SRAM 111 of the first embodiment described above. The other components of the SRAM 211 are similar to the components of the SRAM 111 of the first embodiment described above.

The access transistor 133 is connected between the volatile storage node N and the bit line BL1. The access transistor 143 is connected between the volatile storage node NB and the bit line BLB1. Opening/closing of each of the access transistors 133 and 143 is controlled via the word line WL1. At this point of time, the word line WL1 can be connected to the gates of the respective access transistors 133 and 143.

The access transistor 233 is connected between the volatile storage node N and the bit line BL2. The access transistor 243 is connected between the volatile storage node NB and the bit line BLB2. Opening/closing of each of the access transistors 233 and 243 is controlled via the word line WL2. Each of the access transistors 233 and 243 may be an NMOS transistor. At this point of time, the word line WL2 can be connected to the gates of the respective access transistors 233 and 243.

In this manner, in the second embodiment described above, the dual port SRAM 211 is provided as a volatile storage unit in the memory cell 201. Thus, two parallel read or write operations can be performed on the SRAM in one cycle without changing the configuration of the dual port SRAM 211, and a nonvolatile storage function can be added thereto.

### 3. Third Embodiment

In the second embodiment described above, the dual port SRAM 211 is provided as a volatile storage unit in each memory cell 201. In this third embodiment, a two-port SRAM is provided as a volatile storage unit in a memory cell.

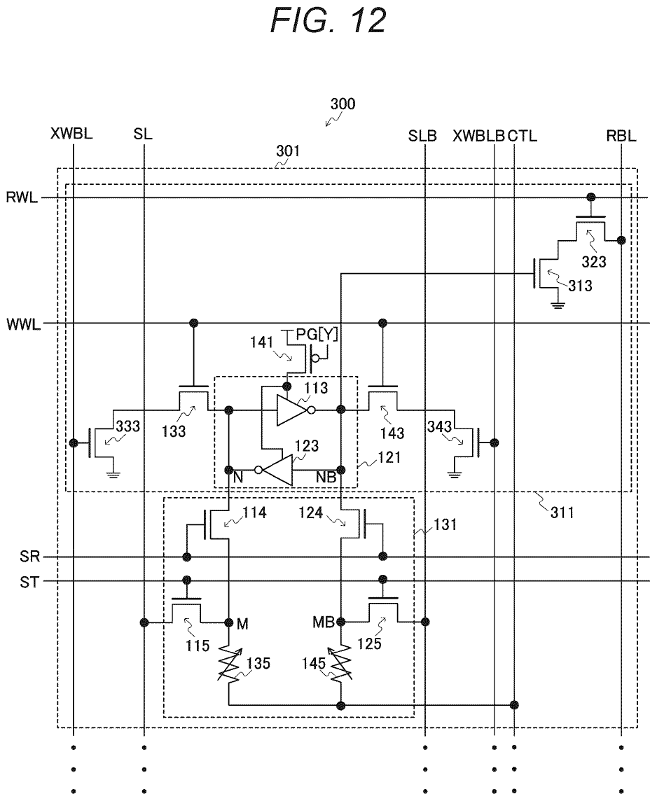

FIG. 12 is a diagram illustrating an example configuration of a memory cell of a storage device according to the third embodiment.

In the drawing, a storage device 300 includes memory cells 301, instead of the memory cells 101 of the first embodiment described above. Also, the storage device 300 includes word lines RWL and WWL as the word lines WL[Y] of the first embodiment described above. Further, the storage device 300 includes bit lines XWBL, XWBLB, and RBL as the bit lines BL[X] and BLB[X] of the first embodiment described above. The other components of the storage device 300 of the third embodiment are similar to the components of the storage device 100 of the first embodiment described above.

A memory cell 301 includes an SRAM 311, instead of the SRAM 111 of the first embodiment described above. The other components of the memory cell 301 are similar to the components of the memory cell 101 of the first embodiment described above.

In the SRAM 311, a read transistor 313, write transistors 333 and 343, and an access transistor 323 are added to the SRAM 111 of the first embodiment described above. The other components of the SRAM 311 are similar to the components of the SRAM 111 of the first embodiment described above.

The read transistor 313 and the access transistor 323 are connected in series. Also, the access transistor 323 is connected to the bit line RBL, and the read transistor 313 is connected to the ground. Further, the gate of the access transistor 323 is connected to the word line RWL, and the gate of the read transistor 313 is connected to the volatile storage node NB.

The write transistor 333 and the access transistor 133 are connected in series. Also, the access transistor 133 is connected to the volatile storage node N, and the write transistor 333 is connected to the ground. Further, the gate of the access transistor 133 is connected to the word line WWL, and the gate of the write transistor 333 is connected to the bit line XWBL.

The write transistor 343 and the access transistor 143 are connected in series. Also, the access transistor 143 is connected to the volatile storage node NB, and the write transistor 343 is connected to the ground. Further, the gate of the access transistor 143 is connected to the word line WWL, and the gate of the write transistor 343 is connected to the bit line XWBLB.

In this manner, in the third embodiment described above, the two-port SRAM 311 is provided as a volatile storage unit in each memory cell 301. Thus, read and write operations can be performed on the SRAM in one cycle without changing the configuration of the two-port SRAM 311, and a nonvolatile storage function can be added thereto.

### 4. Fourth Embodiment

In the first embodiment described above, the power gating transistor 141 that performs header-type power gating is connected to each of the inverters 113 and 123. In this fourth embodiment, a power gating transistor that performs footer-type power gating is connected to each of the inverters 113 and 123.

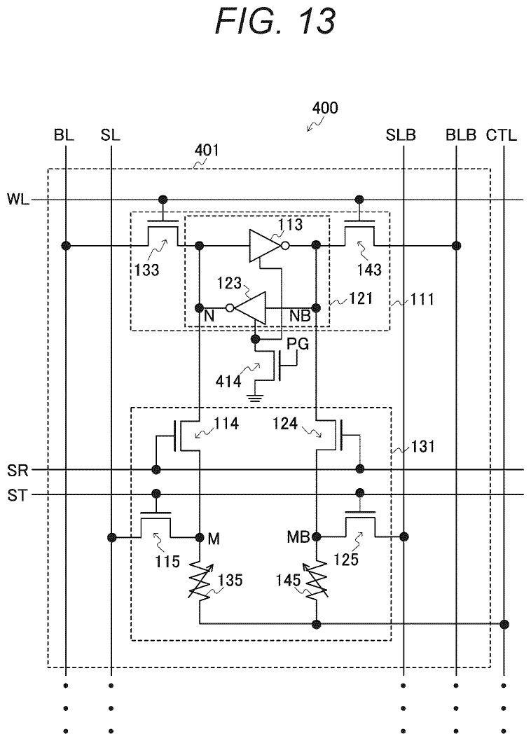

FIG. 13 is a diagram illustrating an example configuration of a memory cell of a storage device according to the fourth embodiment.

In the drawing, a storage device 400 includes a power gating transistor 414, instead of the power gating transistor 141 of the first embodiment described above. The other components of the storage device 400 of the fourth embodiment are similar to the components of the storage device 100 of the first embodiment described above.

The power gating transistor 414 performs power gating of each of the inverters 113 and 123. At this point of time, the power gating transistor 414 can extract the charges accumulated in each of the volatile storage nodes N and NB into the ground. The gate of the power gating transistor 414 is connected to a power gating line PG.

As described above, in the above fourth embodiment, the power gating transistor 414 is connected to each of the inverters 113 and 123, to form a footer-type power gating configuration. Thus, the charges accumulated in each of the nonvolatile storage nodes N and NB can be extracted, and the data held in the resistive random access memory 131 can be restored into the SRAM 111 via the respective restore transistors 114 and 124.

### 5. Fifth Embodiment

In the first embodiment described above, the power gating transistors 141 are provided in the respective memory cells 101. In this fifth embodiment, one power gating transistor is shared among a plurality of memory cells disposed in a memory cell array.

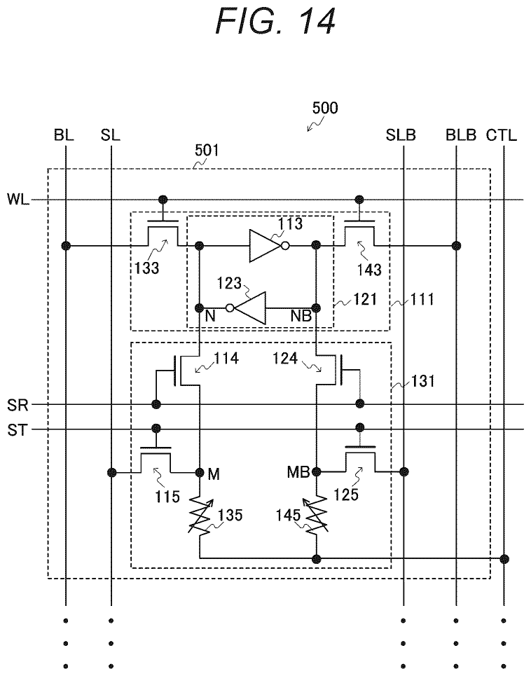

FIG. 14 is a diagram illustrating an example configuration of a memory cell of a storage device according to the fifth embodiment.

In the drawing, a storage device 500 includes memory cells 501, instead of the memory cells 101 of the first embodiment described above. The other components of the storage device 500 of the fifth embodiment are similar to the components of the storage device 100 of the first embodiment described above.

In the memory cell 501, the power gating transistor 141 of the first embodiment described above is omitted. The other components of the memory cell 501 are similar to the components of the memory cell 101 of the first embodiment described above.

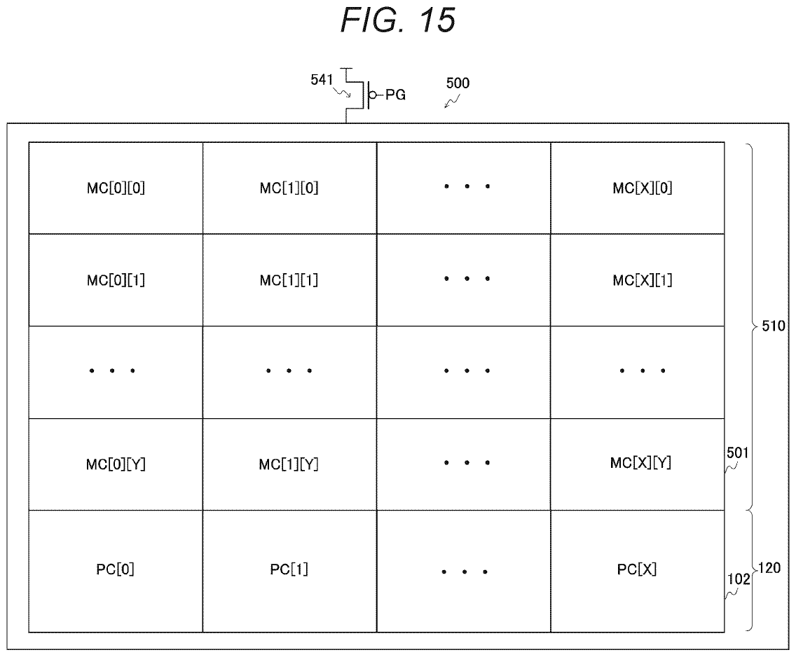

FIG. 15 is a block diagram illustrating an example configuration of the cell array of the storage device according to the fifth embodiment.

In the drawing, the storage device 500 includes a memory cell array 510, instead of the memory cell array 110 of the first embodiment described above. Further, in the storage device 500, a power gating transistor 541 is added to the storage device 100 of the first embodiment described above. The other components of the storage device 500 of the fifth embodiment are similar to the components of the storage device 100 of the first embodiment described above.

In the memory cell array 510, the memory cells 501 are arranged in the row direction and the column direction in a matrix. The power gating transistor 541 is shared among the plurality of memory cells 501 disposed in the memory cell array 510.

The power gating transistor 541 performs power gating of each of the inverters 113 and 123 of the plurality of memory cells 501 disposed in the memory cell array 510. At this point of time, the power gating transistor 541 can extract the charges accumulated in the respective volatile storage nodes N and NB of the plurality of memory cells 501 disposed in the memory cell array 510, into the ground. The gate of the power gating transistor 541 is connected to the power gating line PG.

As described above, in the above fifth embodiment, the single power gating transistor 541 is shared among the plurality of memory cells 501 disposed in the memory cell array 500. Thus, there is no need to provide the power gating transistor 541 in each memory cell 501, and the memory cells 501 can be made smaller in size.

Note that the power gating may be performed on a memory cell basis, a memory cell array basis, a word line basis, a bit line basis, or a power domain basis. At this point of time, header-type power gating may be performed, or footer-type power gating may be performed.

### 6. Sixth Embodiment

In the first embodiment described above, in a case where the data held in the resistive random access memory 131 is to be read, the data held in the resistive random access memory 131 is restored into the SRAM 111, and the data is read from the SRAM 111. In this sixth embodiment, in a case where the data held in the resistive random access memory 131 is to be read, the data held in the resistive random access memory 131 is not restored into the SRAM 111, but is read directly from the resistive random access memory 131.

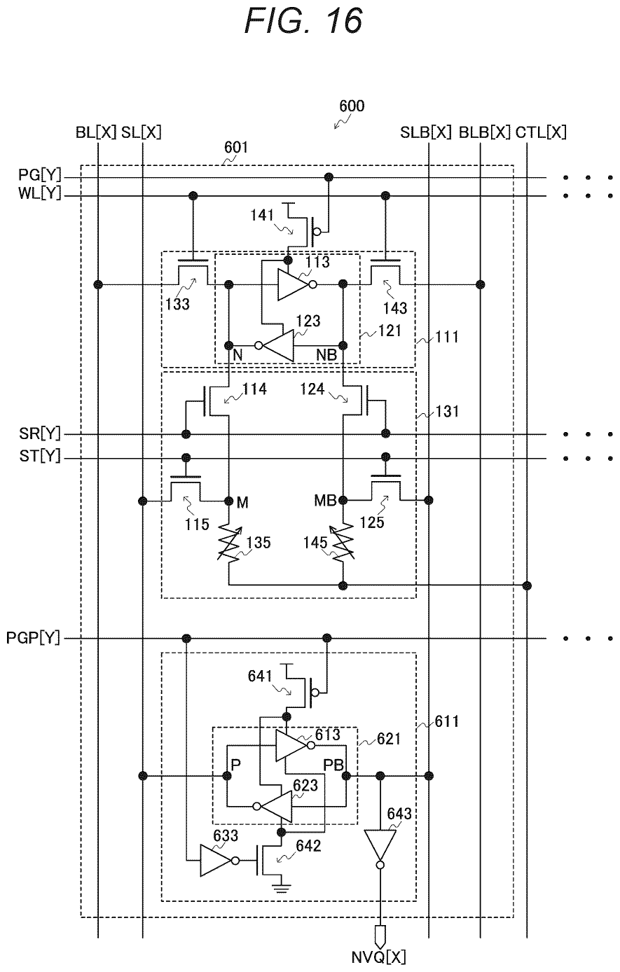

FIG. 16 is a diagram illustrating an example configuration of a memory cell of a storage device according to the sixth embodiment.

In the drawing, a storage device 600 includes memory cells 601, instead of the memory cells 101 of the first embodiment described above. The other components of the storage device 600 of the sixth embodiment are similar to the components of the storage device 100 of the first embodiment described above.

In a memory cell 601, a peripheral restore circuit 611 is added to a memory cell 101 of the first embodiment described above. The other components of the memory cell 601 are similar to the components of the memory cell 101 of the first embodiment described above.

The peripheral restore circuit 611 includes volatile storage nodes P and PB that hold data complementarily. The peripheral restore circuit 611 volatilely holds, in the volatile storage nodes P and PB, the data held in a nonvolatile manner in the nonvolatile storage nodes M and MB of the resistive random access memory 131, and outputs the data to the outside of the memory cell 601 via the volatile storage node PB.

The peripheral restore circuit 611 includes a flip-flop 621, power gating transistors 641 and 642, and inverters 633 and 643. The flip-flop 621 includes inverters 613 and 623.

The input of the inverter 613 is connected to the output of the inverter 623, and the input of the inverter 623 is connected to the output of the inverter 613. At this point of time, the volatile storage node P can be provided at the connecting point between the input of the inverter 613 and the output of the inverter 623, and the volatile storage node PB can be provided at the connecting point between the input of the inverter 623 and the output of the inverter 613. The volatile storage node P is connected to the store line SL[X], and the volatile storage node PB is connected to the store line SLB[X].

The respective power gating transistors 641 and 642 perform power gating of the respective inverters 613 and 623. At this point of time, the power gating transistor 641 can extract the charges accumulated in the respective volatile storage nodes P and PB to the power supply potential. The power gating transistor 642 can extract the charges accumulated in the respective volatile storage nodes P and PB to the ground. The gate of the power gating transistor 641 is connected to a power gating line PGP[Y]. The gate of the power gating transistor 642 is connected to the power gating line PGP[Y] via the inverter 633. The data held in the volatile storage node PB is output as restore data NVQ[X] via the inverter 643.

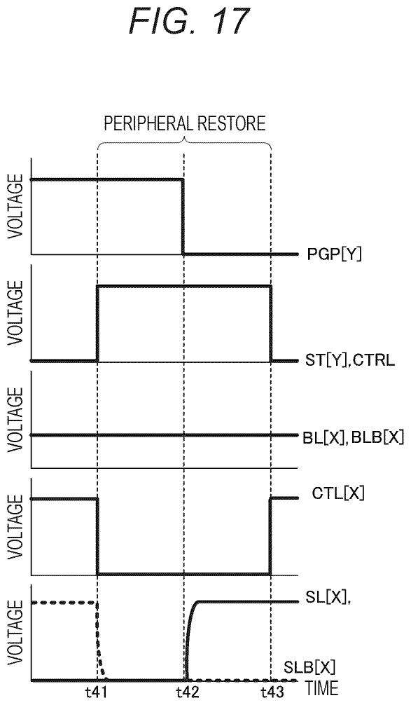

FIG. 17 is a chart showing an example of a voltage waveform of each component of a memory cell during a peripheral restore operation according to the sixth embodiment.

In the drawing, at a time of peripheral restoring into the peripheral restore circuit 611, the respective restore transistors 114 and 124 are turned off via the restore select lines SR[Y], and the SRAM 111 and the resistive random access memory 131 are disconnected from each other. Further, each of the bit lines BL[X] and BLB[X] is put into a floating state (from time t41 to time t43).

The respective store transistors 115 and 125 are then turned on via the store select lines ST[Y], and the store lines SL[X] and SLB[X] are connected to the resistive random access memory 131 (time t41). Further, when the NV control signal CTRL transitions from the low level to the high level, the NV control unit 112 causes the potential of the NV control line CTL[X] to transition from the high level to the low level.

Here, it is assumed that the data ‘1’ is held in the nonvolatile storage node M, the data ‘0’ is held in the nonvolatile storage node MB, the variable resistance element 135 is in a high-resistance state, and the variable resistance element 145 is in a low-resistance state. At this point of time, a low-level voltage is applied to the volatile storage node PB from the NV control line CTL[X] sequentially through the variable resistance element 145, the store transistor 125, and the store line SLB[X], and the data ‘0’ is restored thereinto.

Next, the respective power gating transistors 641 and 642 are turned on via the power gating line PGP[Y] (time t42). At this point of time, data is complementarily held in the respective volatile storage nodes P and PB, and the data ‘1’ is restored into the volatile storage node P.

When the peripheral restoring into the peripheral restore circuit 611 comes to an end, the respective store transistors 115 and 125 are turned off via the store select lines ST[Y], and the NV control signal CTRL transitions from the high level to the low level (time t43).

As described above, in the above sixth embodiment, the data held in the resistive random access memory 131 is restored into the peripheral restore circuit 611 via the respective store lines SL[X] and SLB[X], and the restore data NVQ[X] is read from the peripheral restore circuit 611. Thus, there is no need to operate the SRAM 111 to read the data held in the resistive random access memory 131, and power consumption can be lowered.

### 7. Seventh Embodiment

In the first embodiment described above, there is no limitation on the drive voltage of the SRAM 111 and the drive voltage of the resistive random access memory 131. In this seventh embodiment, the resistive random access memory 131 is driven on the basis of a voltage higher than the drive voltage of the SRAM 111.

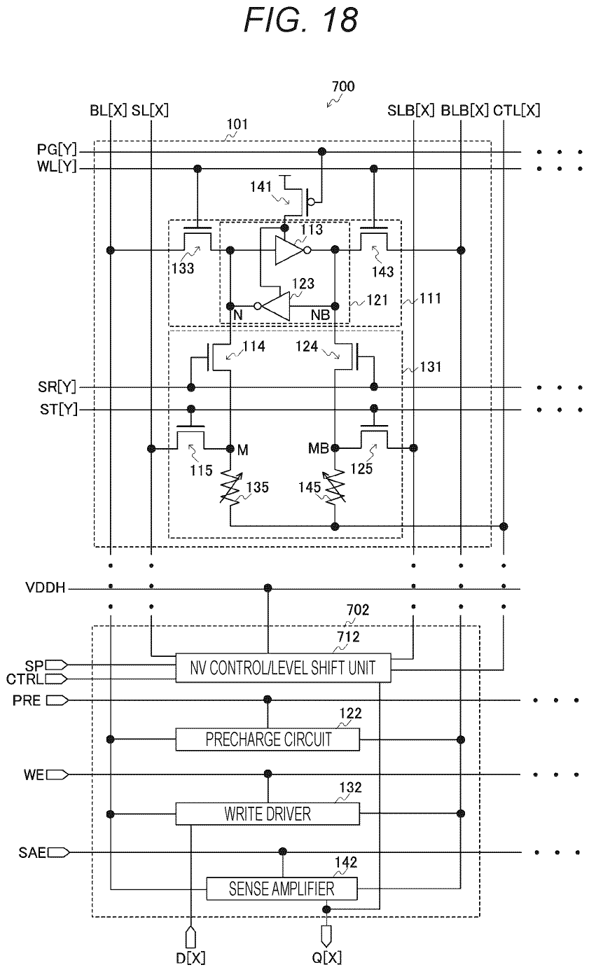

FIG. 18 is a diagram illustrating an example of configurations of a memory cell and a peripheral circuit of a storage device according to the seventh embodiment.

In the drawing, a storage device 700 includes an NV control/level shift unit 712, instead of the NV control unit 112 of the first embodiment described above. The other components of the storage device 700 of the seventh embodiment are similar to the components of the storage device 100 of the first embodiment described above.

The NV control/level shift unit 712 controls storing and restoring in the resistive random access memory 131, on the basis of a store control signal SP and an NV control signal CTRL. A power supply voltage VDDH is supplied to the NV control/level shift unit 712. The power supply voltage VDDH is higher than the power supply voltage to be used for driving the SRAM 111. Here, the NV control/level shift unit 712 controls the potential of each of the store lines SL[X] and SLB[X] and the potential of the NV control line CTL[X] on the basis of data detected by the sense amplifier 142, to conduct storing in the nonvolatile storage nodes M and MB. At this point of time, the NV control/level shift unit 712 can shifts the level of the drive voltage of each of the store lines SL[X] and SLB[X] and the NV control line CTL[X] to a higher level than the drive voltage of the SRAM 111, on the basis of the power supply voltage VDDH.

Further, depending on the characteristics of the respective variable resistance elements 135 and 145, only the voltage to be applied via the store select lines ST[Y] may be increased. Alternatively, not only the voltage to be applied via the store select lines ST[Y], but also the power supply voltage VDDH, the store control signal SP, and the NV control signal CTRL may be made higher in voltage, depending on the characteristics of the respective variable resistance elements 135 and 145. These increases in voltage may be performed by the power supply control circuit 156 shown in FIG. 10.

As described above, in the above seventh embodiment, the resistive random access memory 131 is driven on the basis of a voltage higher than the drive voltage of the SRAM 111. Thus, it becomes possible to cope with high-voltage driving of the resistive random access memory 131 while coping with low-voltage driving of the SRAM 111.

Note that the embodiments described above show examples for embodying the present technology, and the respective matters in the embodiments and the respective matters specifying the invention in the claims have correspondence relationships. Likewise, the matters specifying the invention in the claims and the matters with the same names in the embodiments of the present technology have correspondence relationships. However, the present technology is not limited to the embodiments, and can be embodied by making various modifications to the embodiments without departing from the scope of the present technology. Furthermore, effects described in the present specification are merely examples and are not restrictive, and some other effects may be achieved.

Note that the present technology may also have the following configurations.
(1) A storage device including:
   a volatile storage unit including a volatile storage node that complementarily holds data, and an access transistor connected between the volatile storage node and a bit line; and
   a nonvolatile storage unit including a nonvolatile storage node that complementarily holds the data, a first switch connected between the nonvolatile storage node and a store line, and a second switch connected between the nonvolatile storage node and the volatile storage node.
(2) The storage device according to (1), in which
   the first switch includes a store transistor that stores data held in the volatile storage node into the nonvolatile storage node via the store line, and
   the second switch includes a restore transistor that restores data held in the nonvolatile storage node into the volatile storage node.
(3) The storage device according to (1) or (2), in which
   the volatile storage unit includes a static random access memory (SRAM), and
   the nonvolatile storage unit includes a resistive random access memory.
(4) The storage device according to (2), in which the volatile storage unit includes
   a flip-flop having the volatile storage node,
   the nonvolatile storage unit includes
   a variable resistance element whose resistance changes on the basis of voltage application, and
   one end of the store transistor and one end of the restore transistor are connected to one end of the variable resistance element.
(5) The storage device according to (4), in which
   the flip-flop includes a pair of inverters whose outputs are connected to each other's input,
   a connecting point between the outputs and the inputs of the pair of inverters is used as the volatile storage node, and
   a connecting point among the variable resistance element, the store transistor, and the restore transistor is used as the nonvolatile storage node.
(6) The storage device according to claim 5, in which the data held in the volatile storage node is stored into the nonvolatile storage node sequentially via the store line and the store transistor.
(7) The storage device according to (5), in which data held in the nonvolatile storage node is restored into the volatile storage node via the restore transistor.
(8) The storage device according to (5), further including:
   a word line that opens and closes the access transistor;
   a restore select line that opens and closes the restore transistor;
a store select line that opens and closes the store transistor; and
   a nonvolatile (NV) control line connected to the variable resistance element.
(9) The storage device according to (8), further including:
   a sense amplifier that detects data read from the volatile storage unit; and
   an NV control unit that controls a potential of the store line and a potential of the NV control line on the basis of the data detected by the sense amplifier, and stores the data held in the volatile storage node into the nonvolatile storage node via the store transistor.
(10) The storage device according to (9), in which,
   when the data held in the volatile storage node is stored into the nonvolatile storage node, the NV control unit complementarily sets the potential of the store line depending on the data detected by the sense amplifier, and causes the potential of the NV control line to transition between a high level and a low level.
(11) The storage device according to (10), in which
   the NV control unit drives the nonvolatile storage unit on the basis of a higher voltage than a drive voltage of the volatile storage unit.
(12) The storage device according to any one of (5) to (10), further including
   a power gating transistor that performs power gating of the inverter.
(13) The storage device according to any one of (5) to (10), in which
   a drive force of the store transistor is greater than a drive force of a transistor used in the inverter, a drive force of the access transistor, and a drive force of the restore transistor.
(14) The storage device according to (8), further including
   memory cells in which the volatile storage unit and the nonvolatile storage unit are provided, in which the memory cells are arranged in a row direction and a column direction in a matrix.
(15) The storage device according to (14), in which
   each of the word line, the restore select line, and the store select line extends in the row direction, and
   each of the bit line, the store line, and the NV control line extends in the column direction.
(16) The storage device according to any one of (1) to (15), in which
   the volatile storage unit includes a dual port SRAM.
(17) The storage device according to any one of (1) to (15), in which
   the volatile storage unit includes a two-port SRAM.
(18) The storage device according to any one of (1) to (17), further including
   a peripheral restore circuit that reads data held in the nonvolatile storage node to the outside of the volatile storage unit.
(19) The storage device according to (18), in which
   the data held in the nonvolatile storage node is restored into the peripheral restore circuit sequentially via the store transistor and the store line.

### REFERENCE SIGNS LIST

100 to 700 Storage device
101 Memory cell
102 Column processing unit
111 SRAM
121 Flip-flop
131 Resistive random access memory
112 NV control unit
122 Precharge circuit
132 Write driver
142 Sense amplifier
113, 123 Inverter
133, 143 Access transistor
114, 124 Restore transistor
115, 125 Store transistor
135, 145 Variable resistance element
141 Power gating transistor
BL, BLB Bit line
WL Word line
SL, SLB Store line
CTL NV control line
SR Restore select line
ST Store select line
PG Power gating line
SP Store control signal
CTRL NV control signal
PRE Precharge enable signal
WE Write enable signal
SAE Sense enable signal

1. A storage device comprising:
a volatile storage unit including a volatile storage node that complementarily holds data, and an access transistor connected between the volatile storage node and a bit line; and
a nonvolatile storage unit including a nonvolatile storage node that complementarily holds the data, a first switch connected between the nonvolatile storage node and a store line, and a second switch connected between the nonvolatile storage node and the volatile storage node.

2. The storage device according to claim 1, wherein
the first switch includes a store transistor that stores data held in the volatile storage node into the nonvolatile storage node via the store line, and
the second switch includes a restore transistor that restores data held in the nonvolatile storage node into the volatile storage node.

3. The storage device according to claim 1, wherein
the volatile storage unit includes a static random access memory (SRAM), and
the nonvolatile storage unit includes a resistive random access memory.

4. The storage device according to claim 2, wherein
the volatile storage unit includes a flip-flop having the volatile storage node,
the nonvolatile storage unit includes
a variable resistance element whose resistance changes on a basis of voltage application, and
one end of the store transistor and one end of the restore transistor are connected to one end of the variable resistance element.

5. The storage device according to claim 4, wherein
the flip-flop includes a pair of inverters whose outputs are connected to each other's input,
a connecting point between the outputs and the inputs of the pair of inverters is used as the volatile storage node, and
a connecting point among the variable resistance element, the store transistor, and the restore transistor is used as the nonvolatile storage node.

6. The storage device according to claim 5, wherein the data held in the volatile storage node is stored into the nonvolatile storage node sequentially via the store line and the store transistor.

7. The storage device according to claim 5, wherein the data held in the nonvolatile storage node is restored into the volatile storage node via the restore transistor.

8. The storage device according to claim 5, further comprising:
a word line that opens and closes the access transistor;
a restore select line that opens and closes the restore transistor;
a store select line that opens and closes the store transistor; and
a nonvolatile (NV) control line connected to the variable resistance element.

9. The storage device according to claim 8, further comprising:
a sense amplifier that detects data read from the volatile storage unit; and
an NV control unit that controls a potential of the store line and a potential of the NV control line on a basis of the data detected by the sense amplifier, and stores the data held in the volatile storage node into the nonvolatile storage node via the store transistor.

10. The storage device according to claim 9, wherein,
when the data held in the volatile storage node is stored into the nonvolatile storage node, the NV control unit complementarily sets the potential of the store line depending on the data detected by the sense amplifier, and causes the potential of the NV control line to transition between a high level and a low level.

11. The storage device according to claim 10, wherein
the NV control unit drives the nonvolatile storage unit on a basis of a higher voltage than a drive voltage of the volatile storage unit.

12. The storage device according to claim 5, further comprising
a power gating transistor that performs power gating of the inverter.

13. The storage device according to claim 5, wherein
a drive force of the store transistor is greater than a drive force of a transistor to be used in the inverter, a drive force of the access transistor, and a drive force of the restore transistor.

14. The storage device according to claim 8, further comprising
memory cells in which the volatile storage unit and the nonvolatile storage unit are provided, wherein
the memory cells are arranged in a row direction and a column direction in a matrix.

15. The storage device according to claim 14, wherein
each of the word line, the restore select line, and the store select line extends in the row direction, and
each of the bit line, the store line, and the NV control line extends in the column direction.

16. The storage device according to claim 1, wherein
the volatile storage unit includes a dual port SRAM.

17. The storage device according to claim 1, wherein
the volatile storage unit includes a two-port SRAM.

18. The storage device according to claim 1, further comprising
a peripheral restore circuit that reads data held in the nonvolatile storage node to the outside of the volatile storage unit.

19. The storage device according to claim 18, wherein
the data held in the nonvolatile storage node is restored into the peripheral restore circuit sequentially via the store transistor and the store line.
